(19) United States
(12) Patent Application Publication
(10) Pub. No.: US 2024/0223229 A1
(43) Pub. Date: Jul. 4, 2024

(54) APPARATUSES AND METHODS FOR DETERMINING WHETHER A PREDISTORTION IS TO BE UPDATED

(71) Applicant: Intel Corporation, Santa Clara, CA (US)

(72) Inventors: Albert MOLINA, Novelda (ES); Kameran AZADET, San Ramon, CA (US); Hazar YUKSEL, San Francisco, CA (US)

(21) Appl. No.: 18/147,725

(22) Filed: Dec. 29, 2022

(51) Int. Cl. H04B 1/04; H03F 3/24

(52) U.S. Cl. CPC H04B 1/0475; H03F 3/245; H03F 2200/451; H04B 2001/0425

(57) ABSTRACT

An apparatus is proposed comprising interface circuitry configured to receive a plurality of samples causing an output signal of a power amplifier. The apparatus further comprises processing circuitry configured to allocate at least one sample of the plurality of samples to a bin based on a characteristic of the at least one sample and determine whether a predistortion for samples allocated to the bin is to be updated based on a number of samples allocated to the bin.

### BACKGROUND

The use of a predistortion for a power amplifier may increase the hardware and computational complexity of a transmitter. Hence, there may be a demand for improved predistortion.

### BRIEF DESCRIPTION OF THE FIGURES

Some examples of apparatuses and/or methods will be described in the following by way of example only, and with reference to the accompanying figures, in which

FIG. 1 illustrates an example of an apparatus;

FIG. 2 illustrates an example of a histogram;

FIG. 3 illustrates an example of a determination whether a predistortion is to be updated;

FIG. 4 illustrates another example of an apparatus;

FIG. 5 illustrates an example of a transmitter;

FIG. 6 illustrates an example of a base station;

FIG. 7 illustrates an example of a mobile device;

FIG. 8 illustrates an example of a method; and

FIG. 9 illustrates another example of a method.

### DETAILED DESCRIPTION

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e., only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

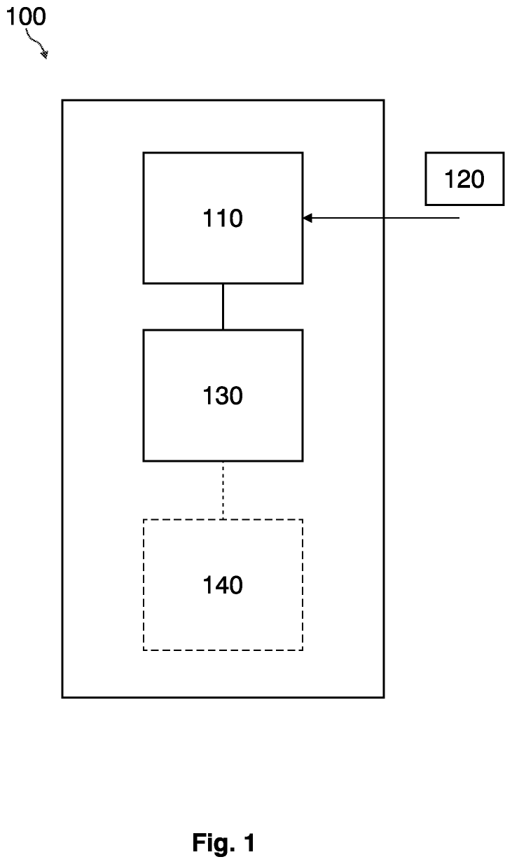

FIG. 1 illustrates an example of an apparatus 100. The apparatus 100 is to be considered in the context of predistortion for a power amplifier. The predistortion may serve a modification of an input signal such that an output signal generated by the power amplifier based on the modified input signal is close to a desired response to the input signal. Additionally or alternatively, the predistortion may serve a modification of a bias signal supplied to the power amplifier for generating the output signal based on the input signal. For instance, the predistortion may serve a compensation of a non-linear behavior of the power amplifier and therefore increase linearization between the input signal and the output signal.

For example, the apparatus 100 may be integrated into or communicatively coupled to a predistortion learning architecture. The apparatus 100 may be integrated into or communicatively coupled to an electronic circuitry (e.g., a predistortion learning component) which determines the predistortion, e.g., based on a learning technique such as an iterative, direct or indirect learning technique. The apparatus 100 may, for instance, select, specify or manipulate training data (samples of the input signal and respective samples of the output signal) which is used for learning by the predistortion learning component. Such an electronic circuitry may be coupled to a predistorter (circuitry) upstream to the power amplifier which applies the determined predistortion to the input signal (and/or to the bias signal). The power amplifier may then amplify the (predistorted) input signal, yielding the output signal.

The apparatus 100 comprises interface circuitry 110 configured to receive a plurality of samples 120 (the input signal) causing the output signal of the power amplifier. For instance, the power amplifier may generate the output signal based on the plurality of samples 120. The interface circuitry 110 may be communicatively coupled to an electronic device which gen-erates the plurality of samples 120, e.g., a baseband processing circuitry, in order to receive the plurality of samples 120.

The interface circuitry 110 may be any means for communicating. The interface circuitry 110 may correspond to one or more inputs and/or outputs for receiving and/or transmitting information, which may be in digital (bit) values according to a specified code, within a module, between modules or between modules of different entities. For example, the interface circuitry 110 may comprise circuitry configured to receive and/or transmit information.

The plurality of samples 120 may indicate a respective amplitude of an electric current or voltage or an electric power. The plurality of samples 120 thereby may encode an information. Said information may be intended for transmission, e.g., by an antenna downstream of the power amplifier.

The apparatus 100 further comprises processing circuitry 130. For example, the processing circuitry 130 (or means for processing 130) may be implemented using one or more processing units, one or more processing devices, any means for processing, such as a processor, a computer or a programmable hardware component being operable with accordingly adapted software. In other words, the described function of the processing circuitry 130 or means for processing may as well be implemented in software, which is then executed on one or more programmable hardware components. Such hardware components may comprise a general-purpose processor, a Digital Signal Processor (DSP), a micro-controller, etc. For instance, the processing circuitry may be integrated into a computer, a processor, a control unit, a (field) programmable logic array ((F)PLAs), a (field) programmable gate array ((F)PGAs), a graphics processor unit (GPU), an application-specific integrated circuit (ASICs), an integrated circuit (ICs) or a system-on-a-chip (SoCs) system programmed to execute the functions of the processing circuitry 130 explained herein.

The processing circuitry 130 is configured to allocate at least one sample (also referred to as the first sample) of the plurality of samples 120 to a bin based on a characteristic of the at least one sample. The allocation of the sample to the bin may be understood as binning (data bucketing or quantization). The bin may, e.g., represent a value range of the characteristic and may be labelled by a bin value representative of the value range, e.g., a mean or median of the value range. The processing circuitry 130 may allocate the sample by matching its characteristic to the bin, e.g., such that the value of its characteristic falls within the value range of the bin. The original value of the characteristic of the sample may be replaced by the bin value of the bin it is allocated to.

The characteristic may be any characteristic of the sample. For instance, the characteristic may be related to a distortion of the output signal, e.g., the characteristic may have an influ-ence on the distortion. The distortion of the output signal may be caused by a non-linear behavior of the power amplifier and lead to an undesired modification of the output signal which the predistortion is intended to counteract on.

The characteristic may be chosen, e.g., depending on how the distortion is modelled by the predistorter. The characteristic may be in some examples chosen as amplitude of the input signal. This may be advantageous for cases where the distortion is at least partly modelled by an amplitude-amplitude (AM/AM) conversion and/or an amplitude-phase (AM/PM) conversion representing an amplitude and phase distortion component of the overall distortion as a function of an amplitude of the input signal. Additionally or alternatively, the characteristic may be chosen such that short-term or long-term memory effects contributing to the distortion are considered. For instance, the characteristic may be a power of the sample or a frequency of the sample.

The processing circuitry 130 is further configured to determine whether a predistortion for samples (at least one sample of the plurality of samples 120) allocated to the bin is to be updated based on a number of samples allocated to the bin. For example, the processing circuitry 130 may control a trigger of an update of the predistortion for a bin based on the number of samples in the bin.

For instance, the processing circuitry 130 may determine whether the predistortion for samples allocated to the bin is to be updated by taking into account the number of samples allocated to the bin, e.g., based on a predefined mathematical function between an update flag and the number of samples. In case the update flag is set based on the predefined mathematical function, the interface circuitry 120 may, for instance, output the update flag triggering a predistortion learning component to update the predistortion for samples allocated to the bin.

The determination whether an update is needed may be in any way dependent on the number of samples in the bin. In some examples, the processing circuitry 130 is configured to determine whether the number of samples allocated to the bin (e.g., a bin k) exceeds a predefined threshold (e.g., a predefined threshold 0ₖ≥2) and, if it is determined that the number of samples exceeds the predefined threshold, determine that the predistortion is to be updated. For instance, the processing circuitry 130 may increase a counter every or every i-th (with i≥2) time a sample of the plurality of samples 120 is allocated to the bin for dynamically determining the number of samples. Further, the processing circuitry 130 may compare the counter to the predefined threshold and set the output flag in case of a match. In other examples, the relation between the update flag and the number of samples may be dynamically changing, e.g., time-dependent or based on an operation mode of the power amplifier. For instance, updating may be suppressed for short time periods.

In cases where a predefined threshold is used as explained above, the processing circuitry 130 may, in some examples, be configured to determine whether the number of samples exceeds the predefined threshold by determining a modulus of a division of the number of samples by the predefined threshold. For instance, the processing circuitry 130 may be configured to determine that the number of samples exceeds the predefined threshold if the modulus is zero. The use of a modulus operation may be beneficial for fast and less complex calculation of whether an update is required with processing architectures commonly used for predistortion systems.

The apparatus 100 may enable a selective determination of samples which are taken as basis for the update. The updated predistortion may then be applied to further incoming samples (subsequent of the first sample and, optionally, including the first sample itself) and allocated to the bin, e.g., until the predistortion is updated again. Likewise, the processing circuitry 130 may discard at least one sample of the plurality of samples 120, e.g . . . , not every sample of the plurality of samples 120 allocated to the bin will trigger an update or underlie the update of the predistortion.

The apparatus 100 may enable a limitation of how often samples with an associated characteristic (e.g., metric) are used for updating the predistortion (predistortion adaptation) in order to ensure that a sufficiently high but not more than necessary number of samples of a bin are selected. Conventionally, reducing training data (samples taken for updating the predistortion) may worsen ill-conditioning of the equation system (predistortion model), which may lead to overfitting (wrongful extraction of model parameters). By contrast, the apparatus 100 may significantly decrease the computational complexity of predistortion adaptation by properly selecting a low number of samples and avoid a generalization error caused by said wrongful extraction of model parameters for modelling the predistortion. The apparatus 100 may pre-serve the performance of the predistortion learning or updating, e.g., assessed by adjacent channel leakage ratio (ACLR), while considerably reducing the number of selected samples used for an update of the predistortion. In some applications, the apparatus 100 may reduce the number of selected samples by approximately an order of magnitude. While conventional histogram optimization techniques may result in a limited application of sample selection due to a changing behavior of the power amplifier (e.g., caused by temperature changes or aging) or signals with significantly changing statistics, the apparatus 100 may enable a lightweight predistortion adaptation by histogram-based sample selection.

In some examples, the processing circuitry 130 is configured to allocate a block of at least two consecutive samples of the plurality of samples 120 to the bin based on a characteristic of the block. The block may indicate a data structure of the at least two consecutive samples grouping these samples together. For instance, the processing circuitry 130 may be configured to block the at least two consecutive samples and allocate the blocked at least two consecutive samples to the bin. The block may have a predefined or variable block size or length, thus, grouping a certain number of consecutive samples together. The block size may be optimized for a trade-off between computational complexity and performance of the predistortion (adaptation algorithm).

The characteristic of the block may be a combined characteristic of the consecutive samples of the block. The characteristic of the block may be any characteristic related to a distortion of the output signal. For example, the characteristic may be a mean power or a mean amplitude of the samples of the block.

The apparatus 100 may enable block-wise processing of samples, e.g., for vector processing which is more efficient when working on blocks instead of individual samples. In some examples, the processing circuitry 130 is a vector processor (or array processor). The apparatus 100 may therefore allow efficient and effective vector operations on large one-dimensional arrays of data. This may be especially advantageous for applications where the processing circuitry 130 also takes on the task of updating the predistortion. Therefore, the apparatus 100 may support an integration of sample selection into the predistortion learning component and/or the predistorter.

Since in many applications, the predistortion may be required to undergo ongoing updates, the processing circuitry 130 may proceed with other samples of the plurality of samples 120 in the same way as described above with respect to the first sample. In some examples, the processing circuitry 130 is further configured to process the plurality of samples 120 and determine, for each (or at least one) bin of a plurality of bins, whether a predistortion for samples allocated to said bin is to be updated based on a respective number of samples allocated to said bin. For instance, each of the plurality of samples 120 may be allocated to one of the plurality of bins. The distribution of the samples over bins may enable histogram-based selection of samples (or block of samples) which are input into a predistortion learning component. Further, the trigger of an update of the predistortion based on the number of samples may decrease the probability that a sample (or block of samples) of a bin is selected for updating the predistortion if the same bin has recently been updated. This may avoid erroneous modelling of the predistortion and redundant updates.

In some examples, the processing circuitry 130 may be configured to determine, for each (or at least one) bin of the plurality of bins, whether the respective number of samples allocated to said bin exceeds a respective predefined threshold and, if it is determined that the number of samples allocated to said bin exceeds the respective predefined threshold, determine that the predistortion for samples allocated to said bin is to be updated. The predefined thresholds may, in some examples, differ from bin to bin. The latter may be beneficial to introduce additional histogram optimizations.

Depending on the application, it may be beneficial, e.g., to increase the level of integration, to further implement the function of at least one of the sample selection, the update of the predistortion and the predistorter by the apparatus 100. Therefore, in some examples, the processing circuitry 130 is further configured to, if it is determined that the predistortion is to be updated, select at least one sample of the plurality of samples (or at least one block of samples) allocated to the bin for updating the predistortion. For example, the first sample may be selected for updating the predistortion. Additionally or alternatively, another sample of the bin subsequent to or preceding the first sample may be selected.

In yet further examples, the processing circuitry 130 is further configured to update the predistortion based on the selected sample allocated to the bin. For instance, the processing circuitry 130 may execute a predistortion learning technique, e.g., any machine learning or control technique which aims at decreasing a difference between an output sample of the power amplifier and a desired value expected for a corresponding input sample. For instance, the processing circuitry 130 may update the predistortion by (re)determining a coefficient (or parameter) of a model assumed for the behavior of the power amplifier (or the distortion pro-duced by the power amplifier) in order to readjust or refit the model based on the selected sample. For example, the processing circuitry 130 may derive the AM/AM and AM/PM con-versions of the power amplifier from raw measurement data (the selected sample) by using averaging or polynomial fitting. In other examples, any other model may be used such as a memoryless model, e.g., power series or polynomial model, or a linear or a non-linear memory model, e.g., Volterra-based model.

As explained above, the processing circuitry 130 may, in some examples, further be configured to apply the updated predistortion to at least one sample (second sample) of the plurality of samples allocated to the bin and subsequent to the selected sample. For instance, the processing circuitry 130 may modify (pre-distort) the second sample based on the updated model of the power amplifier model, e.g., the processing circuitry 130 may set a filter based on the updated model and apply the newly set filter to the second sample. In some examples, the predistortion is a digital predistortion. Alternatively, the predistortion may be an analog predistortion.

For further operation of the power amplifier with the updated predistortion, the apparatus 100 may further comprise memory 140 configured to store data indicating the updated predistortion. For instance, the memory 140 may be configured to store the data in a look-up-table (LUT). For a given amplitude of an input sample, the LUT may index, e.g., corresponding AM/AM and AM/PM conversion values.

In some examples, the memory 140 may include one or more of volatile memory including Dynamic Random Access Memory (DRAM) and/or Synchronous Dynamic Random Access Memory (SDRAM), and Non-Volatile Memory (NVM) including high-speed electrically erasable memory (commonly referred to as Flash memory), Phase change Random Access Memory (PRAM), Magnetoresistive Random Access Memory (MRAM) and/or a three-dimensional crosspoint (3D XPoint) memory. The memory 140 may be implemented as one or more of solder down packaged integrated circuits, socketed memory modules and plug-in memory cards.

In some examples, the apparatus 100 may further comprise a semiconductor die comprising (integrating) the processing circuitry 130 and the memory 140.

An example application of the apparatus 100 may be a modern wireless communication system, where digital predistortion (DPD) may be required to satisfy stringent requirements on transmitter linearity and efficiency. However, the use of DPD may increase the hardware and computational complexity of transmitters. The apparatus 100 may therefore provide a solution that drastically reduces the computational complexity of DPD adaptation, e.g., for vector processors.

Conventional solutions may lend themselves poorly to vector-processor implementations since they work on single samples and not on blocks of samples of a variable size. Due to their implementation complexity, conventional solutions may be unsuitable to be implemented in a vector processor for lightweight DPD adaptation. By contrast, the apparatus 100 may work on block of samples, and for each block of samples, a decision may be made on whether to use it for DPD adaptation. In this scheme, for DPD adaptation, it may be less likely to select a block of samples if another block of samples in the same histogram bin (when it has a similar metric such as its mean power) has been recently selected.

In the following, a concrete implementation example is explained:

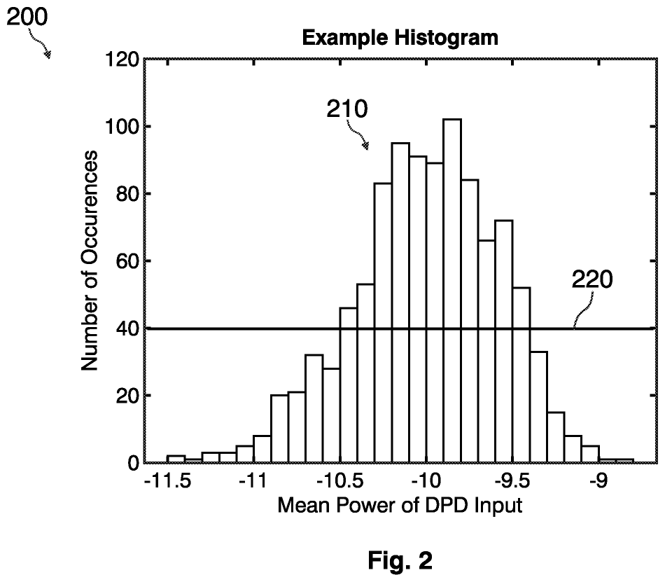

A characteristic (e.g., metric) may be chosen (e.g., mean power of a block of samples) that has a significant statistical relationship to a mean square error of the distortion of the power amplifier. The processing circuitry 130 may compute the metric for a block of samples and assign the block of samples to a histogram bin based on the metric. FIG. 2 illustrates an example of a histogram 200 comprising a plurality of bins 210 (including the said histogram bin). The bins 210 are formed and arranged by a mean power (characteristic) of a DPD input (the plurality of samples 120). The histogram 200 further shows a number of occurrences per bin, i.e., a respective number of samples or block of samples allocated to the bins 210. Further, in FIG. 2, a threshold 220 is set at 40 occurrences at which an update of the predistortion may be triggered. It is to be noted that the histogram 200 shown in FIG. 2 is a mere example. In other examples than the one shown in FIG. 2, a different characteristic may be chosen, the bins 210 may have different (optionally, varying) value ranges, the threshold 220 may be a different value and, optionally, differing among the bins 210.

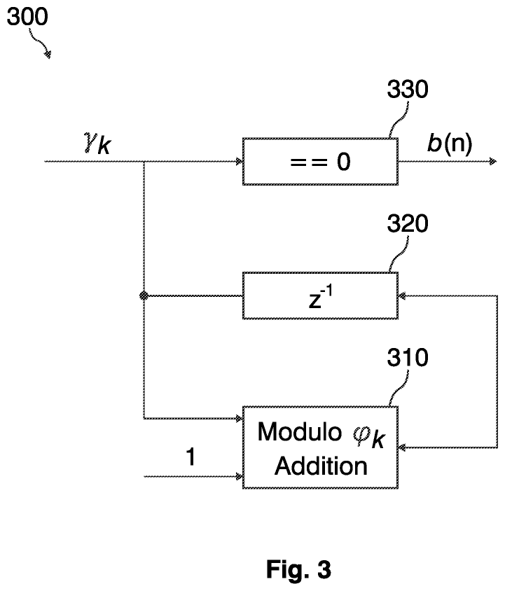

The processing circuitry 130 may, then, update the counter associated with that bin. An example of how the counter may be controlled by the processing circuitry 130 is illustrated by FIG. 3. FIG. 3 shows an example of a block diagram of a determination whether the predistortion of samples allocated to a bin is to be updated based on a number of samples in the bin (block-selection method).

An output of a running counter of a histogram bin k is denoted as yₖ. The processing circuitry 130 may determine whether the number of samples yₖ allocated to the bin k exceeds a predefined threshold by determining, in block 310, a modulus of a modulus vector φ indicating a division of the number of samples by the predefined threshold.

The threshold vector \vec{θ} defines the predefined threshold θₖ for each bin k based on Equation 1.

$$\vec{θ} = [ \begin{matrix}\frac{1}{{θ}_{0}} \\ \frac{1}{{θ}_{1}} \\ ⋮ \\ \frac{1}{{θ}_{{n}_{bins - 1}}}\end{matrix} ] , \qquad Equation 1$$

where each entry comprises an inverse of a respective threshold {θ₀, θ₁, . . . , θₙ_{_{bins-1}}} corresponding to the bin index k of the histogram. The histogram has a number n_{bins} of bins; i.e., 0≤k≤n_{bins-1}

The vector \vec{n}_{occ} indicates the number of occurrences (samples or blocks of samples) for each bin k of the histogram based on Equation 2.

$${\vec{η}}_{occ} = [ \begin{matrix}{η}_{0} \\ {η}_{1} \\ ⋮ \\ {η}_{{n}_{bins - 1}}\end{matrix} ] \qquad Equation 2$$

The modulus vector \vec{φ} is defined by Equation 3:

$$\vec{φ} = ⌈ \vec{θ} ⊙ {\vec{η}}_{occ} ⌉ = [ \begin{matrix}{φ}_{0} \\ {φ}_{1} \\ ⋮ \\ {φ}_{{n}_{bins - 1}}\end{matrix} ] , \qquad Equation 3$$

where ⊙ is an element-wise product and ┌.┐ denotes a ceiling function.

The modulus vector \vec{φ} is then used in block 310 for modulo φₖ addition shown in Equation 4.

In block 320, a delay element z⁻¹ is arranged upstream to block 310. Thus, for a block of samples corresponding to a histogram bin k, there is a running counter whose output is defined by Equation 4:

$${γ}_{k} ← ( {γ}_{k} + 1 ) ( mod {φ}_{k} ) \qquad Equation 4$$

Further, in block 330, the processing circuitry 130 determines that the number of samples exceeds the predefined threshold if the modulus is zero. The block 320 with the label “==0” checks if its input is equal to 0. b(n) is the output of block 330, which is an update flag or a block-selection method label of a block of samples with index n.

For example, the block of samples in a histogram bin k that satisfies the condition of Equation is selected to trigger the update of the predistortion (or is selected to be used for DPD adaptation)

$${γ}_{k} = 0 \qquad Equation 5$$

This means that b(n)=1 for the condition of Equation 5 whereas b(n)=0 denotes that a block of samples with index n has not been selected to be used for DPD adaptation.

DPD coefficients w used for determination of the predistortion may be updated according to Equation 6:

$$\vec{w} ( n ) = \{ \begin{matrix}\vec{w} ( n - 1 ) - \vec{Δ w} , & if b ( n ) = 1 \\ \vec{w} ( n - 1 ) , & if b ( n ) = 0\end{matrix} , \qquad Equation 6$$

where \vec{ΔW} is a DPD coefficient update.

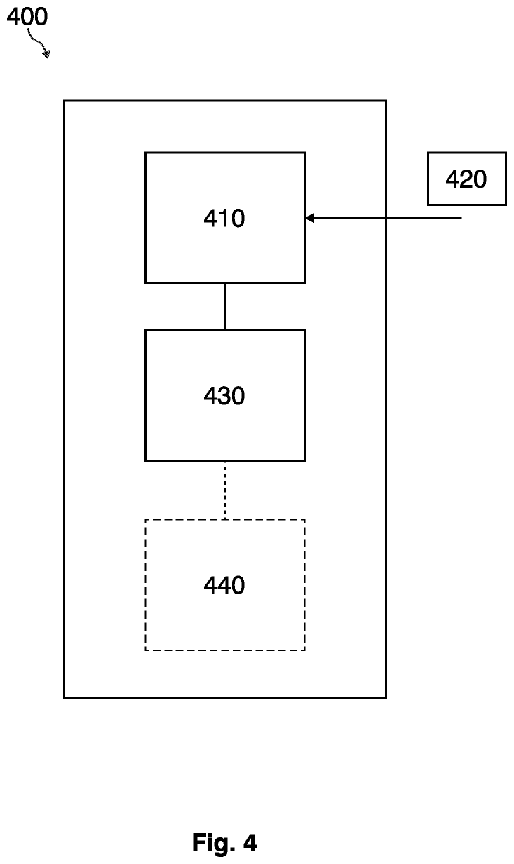

FIG. 4 illustrates another example of an apparatus 400. The apparatus 400 comprises interface circuitry 410 configured to receive a plurality of samples 420 causing an output signal of a power amplifier and processing circuitry 430 configured to bin the plurality of samples based on a characteristic of the plurality of samples and determine whether a predistortion for samples allocated to a bin is to be updated based on a number of samples in the bin.

More details and aspects of the apparatus 400 are explained in connection with the proposed technique or one or more examples described above (e.g., with respect to FIG. 1). The apparatus 400 may comprise one or more additional optional features corresponding to one or more aspects of the proposed technique, or one or more examples described above.

For example, the characteristic may be related to a distortion of the output signal. In some examples, the processing circuitry 430 is configured to arrange at least two consecutive samples of the plurality of samples 420 into a block and bin the block based on a characteristic of the block. For example, the characteristic may be a mean power or a mean amplitude of the at least two consecutive samples.

In some examples, the processing circuitry 430 is configured to determine whether the number of samples allocated to the bin exceeds a predefined threshold and, if it is determined that the number of samples exceeds the predefined threshold, determine that the predistortion is to be updated. In some examples, the processing circuitry 430 is configured to determine whether the number of samples allocated to the bin exceeds the predefined threshold by determining a modulus of a division of the number of samples by the predefined threshold. For instance, the processing circuitry 430 may be configured to determine that the number of samples exceeds the predefined threshold if the modulus is zero.

In some examples, the processing circuitry 430 is a vector processor. In some examples, the processing circuitry 430 is further configured to, if it is determined that the predistortion is to be updated, select at least one sample of the plurality of samples allocated to the bin for updating the predistortion. In yet further examples, the processing circuitry 430 is further con-figured to update the predistortion based on the selected sample allocated to the bin. In some examples, the processing circuitry 430 is further configured to apply the updated predistortion to at least one sample of the plurality of samples allocated to the bin and subsequent to the selected sample. In some examples, the predistortion is a digital predistortion.

In some examples, the apparatus 400 further comprises memory 440 configured to store data indicating the updated predistortion. In some examples, the memory 440 is configured to store the data in a look-up-table.

In some examples, the apparatus 400 further comprises a semiconductor die integrating the processing circuitry 430 and the memory 440.

The apparatus 400 may enable a limitation of how often samples with an associated characteristic are used for updating the predistortion in order to ensure that a sufficiently high but not more than necessary number of samples of a bin are selected. The apparatus 400 may significantly decrease the computational complexity of predistortion adaptation by properly selecting a low number of samples and avoid a generalization error caused by said wrongful extraction of model parameters for modelling the predistortion. The apparatus 400 may further enable block-wise processing of samples.

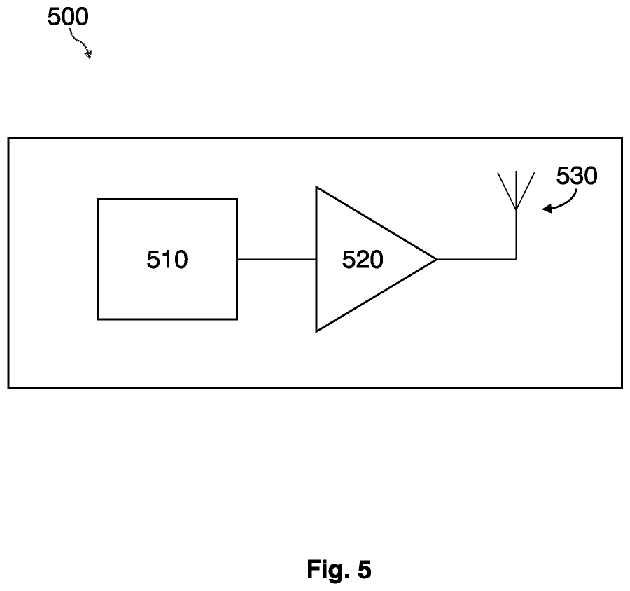

FIG. 5 illustrates an example of a transmitter 500 comprising an apparatus 510 as described herein, such as apparatus 100 or 400. The transmitter 500 further comprises the power amplifier 520 configured to generate the output signal based on the plurality of samples 520. The power amplifier 520 is coupled to the apparatus 510, e.g., directly or via one or more intermediate components, such as a predistorter.

The transmitter 500 optionally comprises at least one antenna 530 configured to radiate a radio frequency transmit signal based on the output signal.

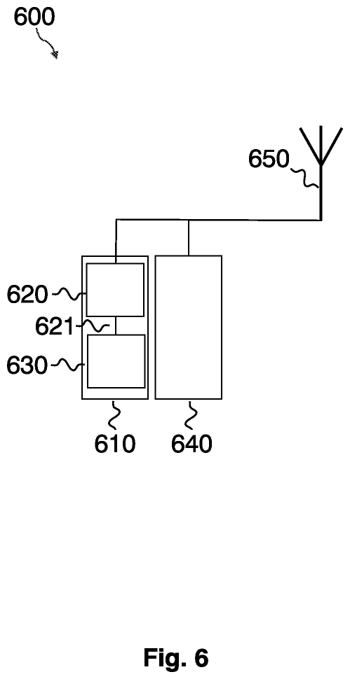

An example of an implementation using an apparatus according to one or more aspects of the architecture described above in connection with FIGS. 1 to 5 or one or more examples described above in connection with FIGS. 1 to 5 is illustrated in FIG. 6. FIG. 6 schematically illustrates an example of a radio base station 600 (e.g., for a femtocell, a picocell, a microcell or a macrocell) comprising a transmitter 610 comprising a power amplifier 620 and an apparatus 621 as described herein.

The base station 600 comprises at least one antenna element 650. The transmitter 610 is coupled to an antenna element 650 for radiating an RF (radio frequency) transmit signal to the environment. The transmitter 610 may be coupled to the antenna element 650 via one or more intermediate element such as one or more of a filter or an up-converter (mixer).

The base station 600 further comprises a baseband processing circuitry 630 configured to generate digital transmit data indicating the plurality of samples. In some examples, the baseband processing circuitry 630 may be implemented, for example, as a solder-down substrate including one or more integrated circuits, a single packaged integrated circuit soldered to a main circuit board or a multi-chip module containing two or more integrated circuits.

The base station 600 further comprises a receiver 640 to receive an RF receive signal, e.g., from the antenna 650 or one or more further antenna elements. The receiver 640 may additionally comprises analog circuitry which may comprise various elements such as one or more of a Low-Noise Amplifier (LNA), a filter, a down-converter (mixer), ElectroStatic Discharge (ESD) protection circuitry, an attenuator etc. For example, the analog circuitry may be con-figured to generate an analog signal based on the RF receive signal received from the antenna element 650 or another antenna element.

To this end, a base station with improved predistortion may be provided allowing the base station to achieve decreased circuitry complexity and increased accuracy.

The base station 600 may comprise further elements such as, e.g., an application processor, a baseband processor, memory, a network controller, a user interface, power management circuitry, a satellite navigation receiver, a network interface controller or power tee circuitry.

In some aspects, the application processor may include one or more Central Processing Unit (CPU) cores and one or more of cache memory, a Low-DropOut (LDO) voltage regulator, interrupt controllers, serial interfaces such as Serial Peripheral Interface (SPI), Inter-Integrated Circuit (I²C) or universal programmable serial interface module, Real Time Clock (RTC), timer-counters including interval and watchdog timers, general purpose Input-Output (IO), memory card controllers such as Secure Digital (SD)/MultiMedia Card (MMC) or similar, Universal Serial Bus (USB) interfaces, Mobile Industry Processor Interface Alliance (MIPI) interfaces and Joint Test Access Group (JTAG) test access ports.

In some examples, the power management (integrated) circuitry may include one or more of voltage regulators, surge protectors, power alarm detection circuitry and one or more backup power sources such as a battery or capacitor. Power alarm detection circuitry may detect one or more of brown out (under-voltage) and surge (over-voltage) conditions.

In some examples, the power tee circuitry may provide for electrical power drawn from a network cable to provide both power supply and data connectivity to the base station using a single cable.

In some examples, the network controller may provide connectivity to a network using a standard network interface protocol such as Ethernet. Network connectivity may be provided using a physical connection which is one of electrical (commonly referred to as copper inter-connect), optical or wireless.

In some examples, the satellite navigation receiver may include circuitry to receive and de-code signals transmitted by one or more navigation satellite constellations such as the Global Positioning System (GPS), GLObalnaya NAvigatSionnaya Sputnikovaya Sistema (GLONASS), Galileo and/or BeiDou. The receiver may provide data to the application processor which may include one or more of position data or time data. The application processor may use time data to synchronize operations with other radio base stations.

In some examples, the user interface may include one or more of physical or virtual buttons, such as a reset button, one or more indicators such as Light Emitting Diodes (LEDs) and a display screen.

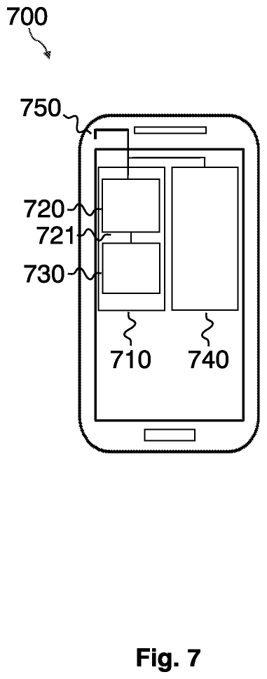

Another example of an implementation using an apparatus according to one or more aspects of the architecture described above in connection with FIGS. 1 to 5 or one or more examples described above in connection with FIGS. 1 to 5 is illustrated in FIG. 7. FIG. 7 schematically illustrates an example of a mobile device 700 (e.g., mobile phone, smartphone, tablet-com-puter, or laptop) comprising an apparatus 721 as proposed.

The mobile device 700 comprises a transmitter 710 as described herein and a receiver 740 configured to receive an RF receive signal. The transmitter 710 comprises a power amplifier 720 configured to generate the output signal based on the plurality of samples. The mobile device 700 further comprises a baseband processing circuitry 730 configured to generate digital transmit data indicating the plurality of samples.

The mobile device 700 comprises at least one antenna element 750. The receiver 740 is coupled to the antenna element 750. The receiver 740 may be coupled to the antenna element 750 via one or more intermediate element such as one or more of a signal line, a filter, etc.

The receiver 740 additionally may comprise analog circuitry configured to supply an analog signal to an ADC. The analog circuitry may comprise various elements such as one or more of a LNA, a filter, a down-converter (mixer), ESD protection circuitry, an attenuator etc. For example, the analog circuitry may be configured to generate the analog signal based on the RF receive signal received from the antenna element 750 or another antenna element (not illustrated) of the mobile device 700.

Additionally, the transmitter 710 is configured to generate an RF transmit signal. The transmitter 710 may use the antenna element 750 or another antenna element (not illustrated) of the mobile device 700 for radiating the RF transmit signal to the environment. For example, the transmitter 710 may be coupled to the antenna element 750 via one or more intermediate elements such as a filter or an up-converter (mixer).

To this end, a mobile device with improved predistortion may be provided allowing the mobile device to achieve decreased circuitry complexity and increased accuracy

The mobile device 700 may comprise further elements such as, e.g., an application processor, a baseband processor, memory, a connectivity module, a Near Field Communication (NFC) controller, an audio driver, a camera driver, a touch screen, a display driver, sensors, remov-able memory, a power management integrated circuit or a smart battery.

In some examples, the application processor may include, for example, one or more CPU cores and one or more of cache memory, LDO regulators, interrupt controllers, serial interfaces such as SPI, I²C or universal programmable serial interface module, RTC, timer-counters including interval and watchdog timers, general purpose input-output (IO), memory card controllers such as SD/MMC or similar, USB interfaces, MIPI interfaces and JTAG test access ports.

In some examples, the baseband processing circuitry 730 may be implemented, for example, as a solder-down substrate including one or more integrated circuits, a single packaged integrated circuit soldered to a main circuit board, and/or a multi-chip module containing two or more integrated circuits.

The baseband processing circuitry 730 may be configured to operate according to one of the 3rd Generation Partnership Project (3GPP)-standardized mobile communication networks or systems. The mobile or wireless communication system may correspond to, for example, a 5^{th} Generation New Radio (5G NR), a Long-Term Evolution (LTE), an LTE-Advanced (LTE-A), High Speed Packet Access (HSPA), a Universal Mobile Telecommunication System (UMTS) or a UMTS Terrestrial Radio Access Network (UTRAN), an evolved-UTRAN (e-UTRAN), a Global System for Mobile communication (GSM), an Enhanced Data rates for GSM Evolution (EDGE) network, or a GSM/EDGE Radio Access Network (GERAN). Alternatively, the wireless communication circuits may be configured to operate according to mobile communication networks with different standards, for example, a Worldwide Inter-operability for Microwave Access (WIMAX) network IEEE 802.16 or Wireless Local Area Network (WLAN) IEEE 802.11, generally an Orthogonal Frequency Division Multiple Access (OFDMA) network, a Time Division Multiple Access (TDMA) network, a Code Division Multiple Access (CDMA) network, a Wideband-CDMA (WCDMA) network, a Frequency Division Multiple Access (FDMA) network, a Spatial Division Multiple Access (SDMA) network, etc.

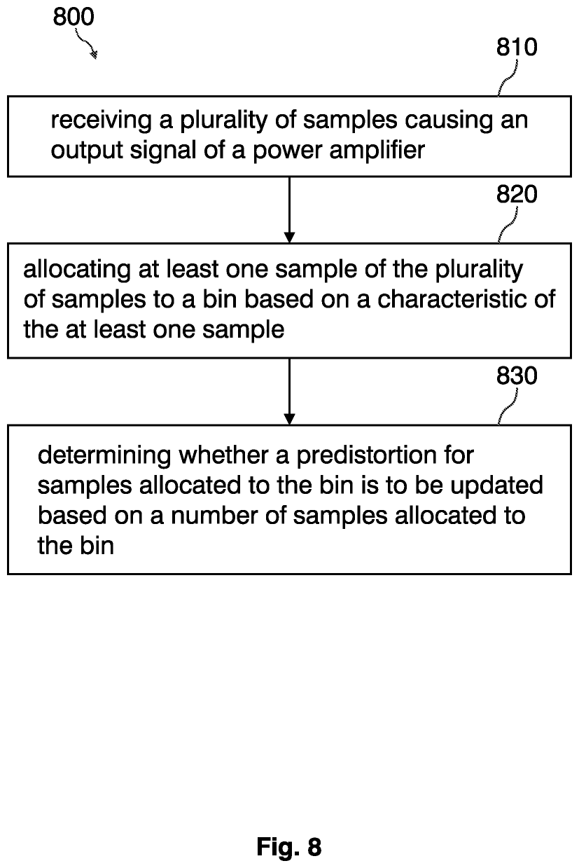

For further illustrating the technique described above, FIG. 8 illustrates a flowchart of an example of a method 800.

The method 800 comprises receiving 810 a plurality of samples causing an output signal of a power amplifier, allocating 820 at least one sample of the plurality of samples to a bin based on a characteristic of the at least one sample and determining 830 whether a predistortion for samples allocated to the bin is to be updated based on a number of samples allocated to the bin.

More details and aspects of the method 800 are explained in connection with the proposed technique or one or more examples described above (e.g., FIGS. 1 to 7). The method 800 may comprise one or more additional optional features corresponding to one or more aspects of the proposed technique, or one or more examples described above.

For example, allocating 820 the at least one sample to the bin may comprise allocating a block of at least two consecutive samples of the plurality of samples to the bin based on a characteristic of the block.

In some examples, the method 800 further comprises determining whether the number of samples allocated to the bin exceeds a predefined threshold and, if it is determined that the number of samples exceeds the predefined threshold, determining that the predistortion is to be updated.

In some examples, determining whether the number of samples allocated to the bin exceeds the predefined threshold comprises determining a modulus of a division of the number of samples by the predefined threshold.

In some examples, the method 800 further comprises processing the plurality of samples and determining, for each bin of a plurality of bins, whether a predistortion for samples allocated to said bin is to be updated based on a respective number of samples allocated to said bin.

In some examples, the method 800 further comprises, if it is determined that the predistortion is to be updated, selecting at least one sample of the plurality of samples allocated to the bin for updating the predistortion.

In some examples, the method 800 further comprises updating the predistortion based on the selected sample allocated to the bin.

In some examples, the method 800 further comprises applying the updated predistortion to at least one sample of the plurality of samples allocated to the bin and subsequent to the selected sample.

In some examples, the method 800 further comprises comprising storing data indicating the updated predistortion. For example, storing the data may comprise storing the data in a look-up-table.

The method 800 may provide a block-selection method. The method 800 may enable a limitation of how often samples with an associated characteristic are used for updating the predistortion in order to ensure that a sufficiently high but not more than necessary number of samples of a bin are selected.

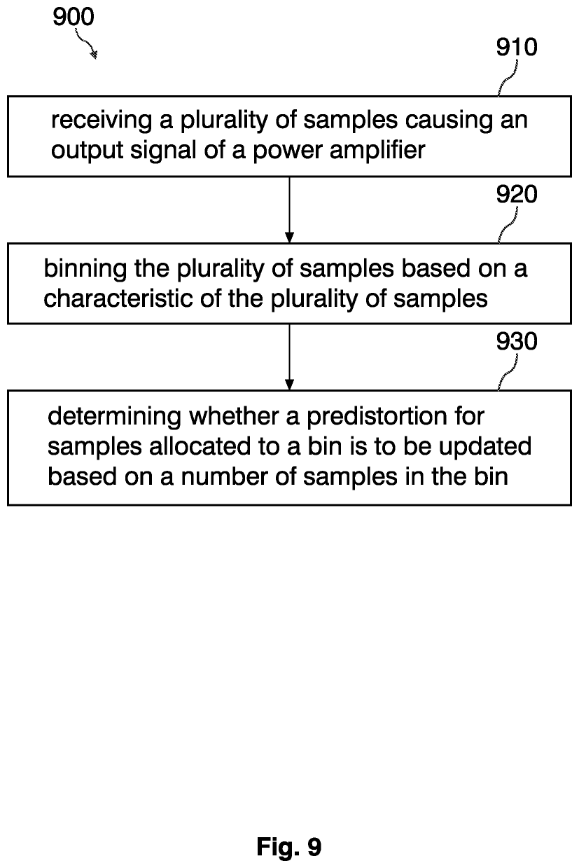

For further illustrating the technique described above, FIG. 9 illustrates a flowchart of another example of a method 900.

The method 900 comprises receiving 910 a plurality of samples causing an output signal of a power amplifier, binning 920 the plurality of samples based on a characteristic of the plurality of samples and determining 930 whether a predistortion for samples allocated to a bin is to be updated based on a number of samples in the bin.

More details and aspects of the method 900 are explained in connection with the proposed technique or one or more examples described above (e.g., FIGS. 1 to 7). The method 900 may comprise one or more additional optional features corresponding to one or more aspects of the proposed technique, or one or more examples described above.

For example, the method 900 may further comprise arranging multiple consecutive samples of the plurality of samples into a block and binning the block based on a characteristic of the block.

In some examples, the method 900 further comprises determining whether the number of samples allocated to the bin exceeds a predefined threshold and, if it is determined that the number of samples allocated to the bin exceeds the predefined threshold, determining that the predistortion is to be updated. For example, determining whether the number of samples exceeds the predefined threshold may comprise determining a modulus of a division of the number of samples by the predefined threshold. For instance, determining whether the number of samples exceeds the predefined threshold may comprise determining that the number of samples exceeds the predefined threshold if the modulus is zero.

In some examples, the method 900 further comprises, if it is determined that the predistortion is to be updated, selecting at least one sample of the plurality of samples allocated to the bin for updating the predistortion. In some examples, the method 900 further comprises updating the predistortion based on the selected sample allocated to the bin. In some examples, the method 900 further comprises applying the updated predistortion to at least one sample of the plurality of samples allocated to the bin and subsequent to the selected sample.

In some examples, the method 900 further comprises storing data indicating the updated predistortion. For instance, storing the data may comprise storing the data in a look-up-table.

The method 900 may provide a block-selection method. The method 900 may enable a limitation of how often samples with an associated characteristic are used for updating the predistortion in order to ensure that a sufficiently high but not more than necessary number of samples of a bin are selected.

In the following, some examples of the proposed technique are presented:

An example (e.g., example 1) relates to an apparatus comprising interface circuitry configured to receive a plurality of samples causing an output signal of a power amplifier, and processing circuitry configured to allocate at least one sample of the plurality of samples to a bin based on a characteristic of the at least one sample, and determine whether a predistortion for samples allocated to the bin is to be updated based on a number of samples allocated to the bin.

Another example (e.g., example 2) relates to a previous example (e.g., example 1) or to any other example, further comprising that the characteristic is related to a distortion of the output signal.

Another example (e.g., example 3) relates to a previous example (e.g., one of the examples 1 or 2) or to any other example, further comprising that the processing circuitry is configured to allocate a block of at least two consecutive samples of the plurality of samples to the bin based on a characteristic of the block.

Another example (e.g., example 4) relates to a previous example (e.g., example 3) or to any other example, further comprising that the characteristic is a mean power or a mean amplitude of the samples of the block.

Another example (e.g., example 5) relates to a previous example (e.g., one of the examples 1 to 4) or to any other example, further comprising that the processing circuitry is configured to determine whether the number of samples allocated to the bin exceeds a predefined threshold, and if it is determined that the number of samples exceeds the predefined threshold, determine that the predistortion is to be updated.

Another example (e.g., example 6) relates to a previous example (e.g., example 5) or to any other example, further comprising that the processing circuitry is configured to determine whether the number of samples exceeds the predefined threshold by determining a modulus of a division of the number of samples by the predefined threshold.

Another example (e.g., example 7) relates to a previous example (e.g., example 6) or to any other example, further comprising that the processing circuitry is configured to determine that the number of samples exceeds the predefined threshold if the modulus is zero.

Another example (e.g., example 8) relates to a previous example (e.g., one of the examples 1 to 7) or to any other example, further comprising that the processing circuitry is a vector processor.

Another example (e.g., example 9) relates to a previous example (e.g., one of the examples 1 to 8) or to any other example, further comprising that the processing circuitry is further con-figured to process the plurality of samples, and determine, for each bin of a plurality of bins, whether a predistortion for samples allocated to said bin is to be updated based on a respective number of samples allocated to said bin.

Another example (e.g., example 10) relates to a previous example (e.g., example 9) or to any other example, further comprising that the processing circuitry is configured to determine, for each bin, whether the respective number of samples allocated to said bin exceeds a respective predefined threshold, and if it is determined that the number of samples allocated to said bin exceeds the respective predefined threshold, determine that the predistortion for samples allocated to said bin is to be updated.

Another example (e.g., example 11) relates to a previous example (e.g., one of the examples 1 to 10) or to any other example, further comprising that the processing circuitry is further configured to, if it is determined that the predistortion is to be updated, select at least one sample of the plurality of samples allocated to the bin for updating the predistortion.

Another example (e.g., example 12) relates to a previous example (e.g., example 11) or to any other example, further comprising that the processing circuitry is further configured to update the predistortion based on the selected sample allocated to the bin.

Another example (e.g., example 13) relates to a previous example (e.g., example 12) or to any other example, further comprising that the processing circuitry is further configured to apply the updated predistortion to at least one sample of the plurality of samples allocated to the bin and subsequent to the selected sample.

Another example (e.g., example 14) relates to a previous example (e.g., one of the examples 1 to 13) or to any other example, further comprising that the predistortion is a digital predistortion.

Another example (e.g., example 15) relates to a previous example (e.g., one of the examples 1 to 14) or to any other example, further comprising memory configured to store data indicating the updated predistortion.

Another example (e.g., example 16) relates to a previous example (e.g., example 15) or to any other example, further comprising that the memory is configured to store the data in a look-up-table.

Another example (e.g., example 17) relates to a previous example (e.g., one of the examples or 16) or to any other example, further comprising a semiconductor die, wherein the semiconductor die comprises the processing circuitry and the memory.

An example (e.g., example 18) relates to an apparatus comprising interface circuitry configured to receive a plurality of samples causing an output signal of a power amplifier, and processing circuitry configured to bin the plurality of samples based on a characteristic of the plurality of samples, and determine whether a predistortion for samples allocated to a bin is to be updated based on a number of samples in the bin.

Another example (e.g., example 19) relates to a previous example (e.g., example 18) or to any other example, further comprising that the characteristic is related to a distortion of the output signal.

Another example (e.g., example 20) relates to a previous example (e.g., one of the examples 18 or 19) or to any other example, further comprising that the processing circuitry is configured to arrange at least two consecutive samples of the plurality of samples into a block, and bin the block based on a characteristic of the block.

Another example (e.g., example 21) relates to a previous example (e.g., example 20) or to any other example, further comprising that the characteristic is a mean power or a mean amplitude of the block.

Another example (e.g., example 22) relates to a previous example (e.g., one of the examples 18 to 21) or to any other example, further comprising that the processing circuitry is configured to determine whether the number of samples allocated to the bin exceeds a predefined threshold, and if it is determined that the number of samples exceeds the predefined threshold, determine that the predistortion is to be updated.

Another example (e.g., example 23) relates to a previous example (e.g., example 22) or to any other example, further comprising that the processing circuitry is configured to determine whether the number of samples allocated to the bin exceeds the predefined threshold by determining a modulus of a division of the number of samples by the predefined threshold.

Another example (e.g., example 24) relates to a previous example (e.g., example 23) or to any other example, further comprising that the processing circuitry is configured to determine that the number of samples exceeds the predefined threshold if the modulus is zero.

Another example (e.g., example 25) relates to a previous example (e.g., one of the examples 18 to 24) or to any other example, further comprising that the processing circuitry is a vector processor.

Another example (e.g., example 26) relates to a previous example (e.g., one of the examples 18 to 25) or to any other example, further comprising that the processing circuitry is further configured to, if it is determined that the predistortion is to be updated, select at least one sample of the plurality of samples allocated to the bin for updating the predistortion.

Another example (e.g., example 27) relates to a previous example (e.g., example 26) or to any other example, further comprising that the processing circuitry is further configured to update the predistortion based on the selected sample allocated to the bin.

Another example (e.g., example 28) relates to a previous example (e.g., example 27) or to any other example, further comprising that the processing circuitry is further configured to apply the updated predistortion to at least one sample of the plurality of samples allocated to the bin and subsequent to the selected sample.

Another example (e.g., example 29) relates to a previous example (e.g., one of the examples 18 to 28) or to any other example, further comprising that the predistortion is a digital predistortion.

Another example (e.g., example 30) relates to a previous example (e.g., one of the examples 18 to 29) or to any other example, further comprising memory configured to store data indicating the updated predistortion.

Another example (e.g., example 31) relates to a previous example (e.g., example 30) or to any other example, further comprising that the memory is configured to store the data in a look-up-table.

Another example (e.g., example 32) relates to a previous example (e.g., one of the examples or 31) or to any other example, further comprising a semiconductor die, wherein the semiconductor die comprises the processing circuitry and the memory.

An example (e.g., example 33) relates to a transmitter, comprising an apparatus according to a previous example (e.g., any one of examples 1 to 32) or to any other example, and the power amplifier configured to generate the output signal based on the plurality of samples.

Another example (e.g., example 34) relates to a previous example (e.g., example 33) or to any other example, further comprising at least one antenna configured to radiate a radio frequency transmit signal based on the output signal.

An example (e.g., example 35) relates to a base station comprising a transmitter according to a previous example (e.g., any one of examples 33 or 34) or to any other example, and a receiver configured to receive a radio frequency receive signal.

Another example (e.g., example 36) relates to a previous example (e.g., example 35) or to any other example, further comprising a baseband processing circuitry con-figured to generate digital transmit data indicating the plurality of samples.

An example (e.g., example 37) relates to a mobile device comprising a transmitter according to a previous example (e.g., any one of examples 33 or 34) or to any other example, and a receiver configured to receive a radio frequency receive signal.

Another example (e.g., example 38) relates to a previous example (e.g., example 37) or to any other example, further comprising a baseband processing circuitry configured to generate digital transmit data indicating the plurality of samples.

An example (e.g., example 39) relates to a method comprising receiving a plurality of samples causing an output signal of a power amplifier, allocating at least one sample of the plurality of samples to a bin based on a characteristic of the at least one sample, and determining whether a predistortion for samples allocated to the bin is to be updated based on a number of samples allocated to the bin.

Another example (e.g., example 40) relates to a previous example (e.g., example 39) or to any other example, further comprising that allocating the at least one sample to the bin comprises allocating a block of at least two consecutive samples of the plurality of samples to the bin based on a characteristic of the block.

Another example (e.g., example 41) relates to a previous example (e.g., one of the examples 39 or 40) or to any other example, further comprising determining whether the number of samples allocated to the bin exceeds a predefined threshold, and if it is determined that the number of samples exceeds the predefined threshold, determining that the predistortion is to be updated.

Another example (e.g., example 42) relates to a previous example (e.g., one of the examples 39 to 41) or to any other example, further comprising that determining whether the number of samples allocated to the bin exceeds the predefined threshold comprises determining a modulus of a division of the number of samples by the predefined threshold.

Another example (e.g., example 43) relates to a previous example (e.g., one of the examples 39 to 42) or to any other example, further comprising processing the plurality of samples, and determining, for each bin of a plurality of bins, whether a predistortion for samples allocated to said bin is to be updated based on a respective number of samples allocated to said bin.

Another example (e.g., example 44) relates to a previous example (e.g., one of the examples 39 to 43) or to any other example, further comprising if it is determined that the predistortion is to be updated, selecting at least one sample of the plurality of samples allocated to the bin for updating the predistortion.

Another example (e.g., example 45) relates to a previous example (e.g., example 44) or to any other example, further comprising updating the predistortion based on the selected sample allocated to the bin.

Another example (e.g., example 46) relates to a previous example (e.g., example 45) or to any other example, further comprising applying the updated predistortion to at least one sample of the plurality of samples allocated to the bin and subsequent to the selected sample.

Another example (e.g., example 47) relates to a previous example (e.g., one of the examples 39 to 46) or to any other example, further comprising storing data indicating the updated predistortion.

Another example (e.g., example 48) relates to a previous example (e.g., example 47) or to any other example, further comprising that storing the data comprises storing the data in a look-up table.

An example (e.g., example 49) relates to a method comprising receiving a plurality of samples causing an output signal of a power amplifier, binning the plurality of samples based on a characteristic of the plurality of samples, and determining whether a predistortion for samples allocated to a bin is to be updated based on a number of samples in the bin.

Another example (e.g., example 50) relates to a previous example (e.g., example 49) or to any other example, further comprising arranging multiple consecutive samples of the plurality of samples into a block, and binning the block based on a characteristic of the block.

Another example (e.g., example 51) relates to a previous example (e.g., one of the examples 49 or 50) or to any other example, further comprising determining whether the number of samples allocated to the bin exceeds a predefined threshold, and if it is determined that the number of samples allocated to the bin exceeds the predefined threshold, determining that the predistortion is to be updated.

Another example (e.g., example 52) relates to a previous example (e.g., example 51) or to any other example, further comprising that determining whether the number of samples exceeds the predefined threshold comprises determining a modulus of a division of the number of samples by the predefined threshold.

Another example (e.g., example 53) relates to a previous example (e.g., example 52) or to any other example, further comprising that determining whether the number of samples exceeds the predefined threshold comprises determining that the number of samples exceeds the predefined threshold if the modulus is zero.

Another example (e.g., example 54) relates to a previous example (e.g., one of the examples 49 to 53) or to any other example, further comprising if it is determined that the predistortion is to be updated, selecting at least one sample of the plurality of samples allocated to the bin for updating the predistortion.

Another example (e.g., example 55) relates to a previous example (e.g., example 54) or to any other example, further comprising updating the predistortion based on the selected sample allocated to the bin.

Another example (e.g., example 56) relates to a previous example (e.g., example 55) or to any other example, further comprising applying the updated predistortion to at least one sample of the plurality of samples allocated to the bin and subsequent to the selected sample.

Another example (e.g., example 57) relates to a previous example (e.g., one of the examples 49 to 56) or to any other example, further comprising storing data indicating the updated predistortion.

Another example (e.g., example 58) relates to a previous example (e.g., example 57) or to any other example, further comprising that storing the data comprises storing the data in a look-up-table.

Another example (e.g., example 59) relates to a non-transitory machine-readable storage me-dium including program code, when executed, to cause a machine to perform the method of example 39 to 58.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or com-puter-readable and encode and/or contain machine-executable, processor-executable or com-puter-executable programs and instructions. Program storage devices may include or be digital storage devices, magnetic storage media such as magnetic disks and magnetic tapes, hard disk drives, or optically readable digital data storage media, for example.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execu-tion of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. An apparatus comprising:
interface circuitry configured to receive a plurality of samples causing an output signal of a power amplifier; and
processing circuitry configured to:
allocate at least one sample of the plurality of samples to a bin based on a characteristic of the at least one sample; and
determine whether a predistortion for samples allocated to the bin is to be updated based on a number of samples allocated to the bin.

2. The apparatus of claim 1, wherein the characteristic is related to a distortion of the output signal.

3. The apparatus of claim 1, wherein the processing circuitry is configured to allocate a block of at least two consecutive samples of the plurality of samples to the bin based on a characteristic of the block.

4. The apparatus of claim 3, wherein the characteristic is a mean power or a mean amplitude of the samples of the block.

5. The apparatus of claim 1, wherein the processing circuitry is configured to:
determine whether the number of samples allocated to the bin exceeds a predefined threshold; and
if it is determined that the number of samples exceeds the predefined threshold, determine that the predistortion is to be updated.

6. The apparatus of claim 5, wherein the processing circuitry is configured to determine whether the number of samples exceeds the predefined threshold by determining a modulus of a division of the number of samples by the predefined threshold.

7. The apparatus of claim 6, wherein the processing circuitry is configured to determine that the number of samples exceeds the predefined threshold if the modulus is zero.

8. The apparatus of claim 1, wherein the processing circuitry is a vector processor.

9. The apparatus of claim 1, wherein the processing circuitry is further configured to:
process the plurality of samples; and
determine, for each bin of a plurality of bins, whether a predistortion for samples allocated to said bin is to be updated based on a respective number of samples allocated to said bin.

10. The apparatus of claim 9, wherein the processing circuitry is configured to:
determine, for each bin, whether the respective number of samples allocated to said bin exceeds a respective predefined threshold; and
if it is determined that the number of samples allocated to said bin exceeds the respective predefined threshold, determine that the predistortion for samples allocated to said bin is to be updated.

11. The apparatus of claim 1, wherein the processing circuitry is further configured to, if it is determined that the predistortion is to be updated, select at least one sample of the plurality of samples allocated to the bin for updating the predistortion.

12. The apparatus of claim 11, wherein the processing circuitry is further configured to update the predistortion based on the selected sample allocated to the bin.

13. The apparatus of claim 12, wherein the processing circuitry is further configured to apply the updated predistortion to at least one sample of the plurality of samples allocated to the bin and subsequent to the selected sample.

14. The apparatus of claim 1, wherein the predistortion is a digital predistortion.

15. The apparatus of claim 1, further comprising memory configured to store data indicating the updated predistortion.

16. The apparatus of claim 15, wherein the memory is configured to store the data in a look-up-table.

17. The apparatus of claim 15, further comprising a semiconductor die, wherein the semiconductor die comprises the processing circuitry and the memory.

18. A transmitter, comprising:
an apparatus according to claim 1; and
the power amplifier configured to generate the output signal based on the plurality of samples.

19. The transmitter of claim 18, further comprising at least one antenna configured to radiate a radio frequency transmit signal based on the output signal.

20. A base station comprising:
a transmitter according to claim 18; and
a receiver configured to receive a radio frequency receive signal.

21. The base station of claim 20, further comprising a baseband processing circuitry con-figured to generate digital transmit data indicating the plurality of samples.

22. A method comprising:
receiving a plurality of samples causing an output signal of a power amplifier;
binning the plurality of samples based on a characteristic of the plurality of samples; and
determining whether a predistortion for samples allocated to a bin is to be updated based on a number of samples in the bin.

23. The method of claim 22, further comprising:
arranging multiple consecutive samples of the plurality of samples into a block; and
binning the block based on a characteristic of the block.

24. The method of claim 22, further comprising:
determining whether the number of samples allocated to the bin exceeds a predefined threshold; and
if it is determined that the number of samples allocated to the bin exceeds the predefined threshold, determining that the predistortion is to be updated.

25. The method of claim 24, wherein determining whether the number of samples exceeds the predefined threshold comprises determining a modulus of a division of the number of samples by the predefined threshold.
